(19) United States
(12) Patent Application Publication
(10) Pub. No.: US 2006/0124931 A1
(43) Pub. Date: Jun. 15, 2006

(54) Organic electroluminiscence display panel and manufacturing method thereof

(76) Inventors: Joon-Hoo Choi, Seoul (KR); Beohm-Rak Choi, Seoul (KR); Jin-Koo Chung, Seoul (KR)

Correspondence Address: DLA PIPER RUDNICK GRAY CARY US, LLP, 2000 UNIVERSITY AVENUE, E. PALO ALTO, CA, 94303-2248, US

(21) Appl. No.: 10/521,309

(22) PCT Filed: Nov. 27, 2003
(86) PCT No.: PCT/KR03/02591

§ 371 Date: Sep. 12, 2005

(30) Foreign Application Priority Data
Dec. 3, 2002 (KR) 10-2002-0076355

(51) Int. Cl. H01L 29/04

(52) U.S. Cl. 257/59

(57) ABSTRACT

A polysilicon layer is formed on an insulating substrate and a gate insulating layer is formed on the polysilicon layer. A gate line is formed on the gate insulating layer and an interlayer insulating film is formed on the gate line. A data line and a pixel electrode are formed on the interlayer insulating film. A partition is formed on the data line and the pixel electrode and an organic EL layer is formed on the pixel electrode in a predetermined area defined by the partition. A common electrode is formed on the organic EL layer.

### BACKGROUND OF THE INVENTION

(a) Field of the Invention

The present invention relates to an organic electroluminescence display panel and a manufacturing method thereof.

(b) Description of the Related Art

An organic electroluminescence (EL) display contains organic material emitting light in response to a current. The organic material is partitioned into a plurality of islands arranged in a matrix and the intensity of the emitted light is controlled by controlling the current in each island such that an image is displayed. The organic EL display has several advantages such as low voltage driving, lightness and slimness, wide viewing angle, and fast response. Therefore, the organic EL display is a promising next-generation display device.

The organic EL display includes a plurality of pixels arranged in a matrix and each pixel includes a switching element such as a thin film transistor (TFT), a pixel electrode, and an organic EL layer, which include several thin film patterns. The thin film patterns are formed by film deposition and photo-etching, which is a complicated process requiring high cost and long time. Accordingly, the number of the photo-etching steps determines total cost and time for manufacturing the organic EL display panel.

### SUMMARY OF THE INVENTION

A motivation of the present invention is to simplify a method of manufacturing an organic EL display to reduce production cost and time.

According to an aspect of the present invention, a pixel electrode includes the same layer as a data line.

An organic EL display panel is provided, which includes: an insulating substrate; a polysilicon layer formed on the substrate; a gate insulating layer formed on the polysilicon layer; a gate wire formed on the gate insulating layer; an interlayer insulating film formed on the gate wire; a data wire formed on the interlayer insulating film; a pixel electrode formed on the same layer as the data wire; an organic EL layer formed on the pixel electrode and disposed in a predetermined area; a partition formed on the data wire and the pixel electrode and defining the predetermined area; and a common electrode formed on the organic EL layer and the partition.

The pixel electrode preferably includes the same material as the data wire.

The polysilicon layer preferably includes first and second transistor portions including source regions and drain regions and a storage electrode portion connected to the second transistor portion. The gate wire preferably includes first and second gate electrodes and a storage electrode overlapping the first and the second transistor portions and the storage electrode portion, respectively. The data wire preferably includes first and second data lines, a first source electrode connected to the first data line and the source region of the first transistor portion, a first drain electrode connected to the drain region the first transistor portion and the second gate electrode, and a second source electrode connected to the second data line and the source region of the second transistor portion. The pixel electrode is preferably connected to the drain region of the second transistor.

The organic EL display panel may further include a buffer layer disposed between the organic EL layer and the common electrode.

The partition is preferably made of black photoresist.

The organic EL display panel may further include an auxiliary electrode contacting the common electrode.

A method of manufacturing an organic EL display panel is provided, which includes: forming a polysilicon layer on an insulating substrate; forming a gate insulating layer on the polysilicon layer; forming a gate line on the gate insulating layer; forming an interlayer insulating film on the gate line; forming a data line and a pixel electrode on the interlayer insulating film; forming a partition on the data line and the pixel electrode; forming an organic EL layer on the pixel electrode in a predetermined area defined by the partition; and forming a common electrode on the organic EL layer.

The formation of the partition may include: coating a black photoresist; exposing the photoresist to light through a photo mask; and developing the photoresist.

The method may further include: forming an auxiliary electrode contacting the common electrode.

### BRIEF DESCRIPTION OF THE DRAWINGS

The present invention will become more apparent by describing embodiments thereof in detail with reference to the accompanying drawings in which:

FIG. 1 is a layout view of an organic EL display panel according to an embodiment of the present invention;

FIG. 2 is a sectional view of the organic EL display panel shown in FIG. 1 taken along the line II-II′;

FIG. 3 is a sectional view of the organic EL display panel shown in FIG. 1 taken along the line III-III′;

FIG. 4A is a layout view of the organic EL display panel shown in FIGS. 1-3 in a first step of a manufacturing method thereof according to an embodiment of the present invention;

FIGS. 4B and 4C are sectional views of the organic EL display panel shown in FIG. 4A taken along the lines IVB-IVB′ and IVC-IVC′, respectively;

FIG. 5A is a layout view of the organic EL display panel shown in FIGS. 1-3 in a step following the step shown in FIG. 4A;

FIGS. 5B and 5C sectional views of the organic EL display panel shown in FIG. 5A taken along the lines VB-VB′ and VC-VC′, respectively;

FIG. 6A is a layout view of the organic EL display panel shown in FIGS. 1-3 in a step following the step shown in FIG. 5A;

FIGS. 6B and 6C are sectional views of the organic EL display panel shown in FIG. 6A taken along the lines VIB-VIB′ and VIC-VIC′, respectively;

FIG. 7A is a layout view of the organic EL display panel shown in FIGS. 1-3 in a step following the step shown in FIG. 6A; and

FIGS. 7B and 7C are sectional views of the organic EL display panel shown in FIG. 7A taken along the lines VIIB-VIIB′ and VIIC-VIIC′, respectively.

### DESCRIPTION OF REFERENCE NUMERALS IN THE DRAWINGS

70: organic EL layer
123a, 123b: gate electrode
173a, 173b: source electrode
175a: drain electrode
171a: first data line
171b: second data line
153a, 153b: source region
155a, 155b: drain region
154a, 154b: channel region
190: pixel electrode
270: common electrode

### DETAILED DESCRITPION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate or panel is referred to as being “on” another element, it can be directly on the other element or intervening elements may also be present. In contrast, when an element is referred to as being “directly on” another element, there are no intervening elements present.

Then, organic electroluminescence display devices and manufacturing methods thereof according to embodiments of the present invention will be described with reference to the accompanying drawings.

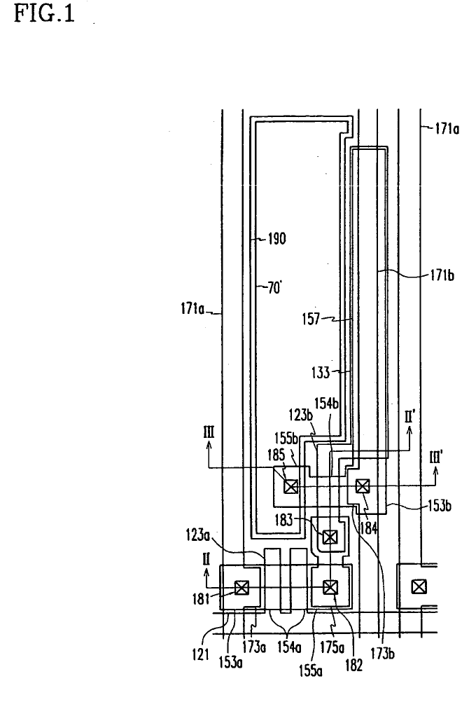

First, an organic EL display according to an embodiment of the present invention is described in detail with reference to FIGS. 1-3.

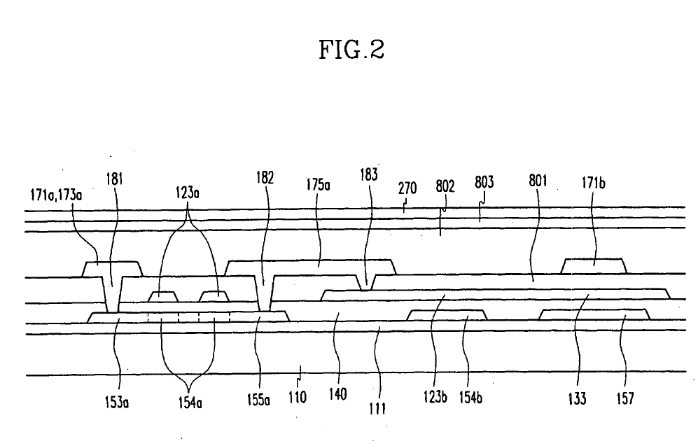

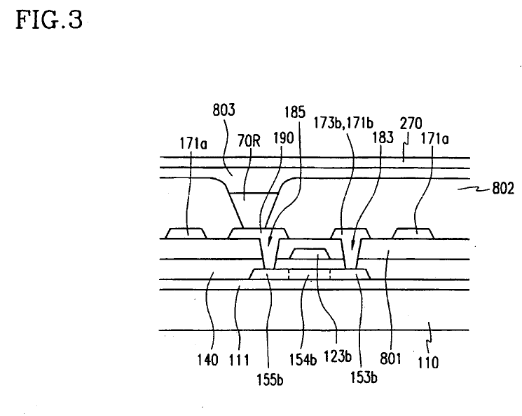

FIG. 1 is a layout view of an organic EL display panel according to an embodiment of the present invention, FIG. 2 is a sectional view of the organic EL display panel shown in FIG. 1 taken along the line II-II′, and FIG. 3 is a sectional view of the organic EL display panel shown in FIG. 1 taken along the line III-III′.

A blocking layer 111 preferably made of silicon oxide is formed on an insulating substrate 110.

A polysilicon layer 153a, 154a, 155a, 153b, 154b, 155b and 157 is formed on the blocking layer 111. The polysilicon layer 153a, 154a, 155a, 153b, 154b, 155b and 157 includes a first transistor portion 153a, 154a and 155a, a second transistor portion 153b, 154b and 155b, and a storage electrode portion 157. The first transistor portion 153a, 154a and 155a includes a (first) source region 153a and a (first) drain region 155a doped with n type impurity as well as a (first) channel portion 154a, while the second transistor portion 153b, 154b and 155b includes a (second) source region 153b and a (second) drain region 155b doped with p type impurity as well as a (second) channel region 154b. Alternatively, the first source region 153a and the drain region 155a are doped with p type impurity, while the second source region 153b and the drain region 155b are doped with n type impurity, depending on driving conditions.

A gate insulating layer 140 preferably made of silicon oxide or silicon nitride is formed on the polysilicon layer 153a, 154a, 155a, 153b, 154b, 155b and 157.

A gate line 121, first and second gate electrodes 123a and 123b, and a storage electrode 133 preferably made of metal such as Al are formed on the gate insulating layer 140. The first gate electrode 123a is branched from the gate line 121 and overlaps the first channel portion 154a, while the second gate electrode 123b is separated from the gate line 121 and overlaps the second channel region 154b. The storage electrode 133 is connected to the second gate electrode 123b, and overlaps the storage electrode portion 157 of the polysilicon layer.

An interlayer insulating film 801 is formed on the gate line 121, the first and the second gate electrodes 123a and 123b, the storage electrode 133.

First and second data lines 171a and 171b, first and second source electrodes 173a and 173b, a drain electrode 175a, and a pixel electrode 190 are formed on the interlayer insulating film 801.

The first source electrode 173a is branched from the first data line 171a and connected to the first source region 153a through a contact hole 181 penetrating the interlayer insulating film 801 and the gate insulating layer 140. The second source electrode 173b is branched from the second data line 171b and connected to the second source region 153b through a contact hole 184 penetrating the interlayer insulating film 801 and the gate insulating layer 140. The drain electrode 175a contacts the first drain region 155a and the second gate electrode 123b through contact holes 182 and 183 penetrating the interlayer insulating film 801 and the gate insulating layer 140 such that the first drain region 155a is electrically connected to the second gate electrode 123b.

The pixel electrode 190 is connected to the second drain region 155b through a contact hole 185 penetrating the interlayer insulating film 801 and the gate insulating layer 140, and it is preferably made of the same layer as the data wire 171a, 171b, 173a, 173b and 175a. The data wire 171a, 171b, 173a, 173b and 175a and the pixel electrode 190 is preferably made of reflective material such as Al. However, the pixel electrode 190 may be formed of a transparent material such as ITO (indium tin oxide) and IZO (indium zinc oxide).

Meanwhile, the second data line 171b overlaps the storage electrode 133.

A partition 802 preferably made of organic insulating material is formed on the data wire 171a, 171b, 173a, 173b and 175a and the pixel electrode 190. The partition 802 surrounds the pixel electrode 190 to define an area filled with an organic EL material. The partition 802 is preferably made of a photosensitive material containing black pigment, which is exposed to light and developed, such that the partition 802 functions as a light blocking layer and a manufacturing method thereof is simplified.

An organic EL layer 70 is formed on the pixel electrode 190 and disposed in the area surrounded by the partition 802. The organic EL layer 70 is preferably made of organic material emitting a primary-color light such as red, green and blue light. The red, green and blue organic EL layers 70 are arranged periodically.

A buffer layer 803 is formed on the organic EL layer 70 and the partition 802. The buffer layer 803 may be omitted if it is not required.

A common electrode 270 is formed on the buffer layer 803. The common electrode 270 is preferably made of transparent conductive material such as ITO and IZO. If the pixel electrode 190 is made of transparent conductive material such as ITO and IZO, the common electrode 270 is preferably made of reflective metal such as Al.

An auxiliary electrode (not shown) made of low resistivity material is optionally provided for compensating the conductivity of the common electrode 270. The auxiliary electrode may be disposed between the common electrode 270 and the buffer layer 803 or on the common electrode 270, and it preferably has a matrix form along the partition 802 such that it does not overlap the organic EL layer 70.

Here, the second data line 171b is connected to a constant voltage.

The driving mechanism of the above-described organic EL display panel is described.

When a gate-on pulse is applied to the gate line 121, the first transistor is turned on to transmit a data voltage from the first data line 171a to the second gate electrode 123b. The application of the data voltage to the second gate electrode 123b turns on the second transistor such that a current from the second data line 171b enters into the common electrode 270 through the pixel electrode 190 and the organic EL layer 70. The organic EL layer 70 receiving the current emits light with a predetermined wavelength. The intensity of the emitted light depends on the current flowing in the organic EL layer 70. The magnitude of the current driven by the second transistor depends on the magnitude of the data voltage supplied from the first transistor.

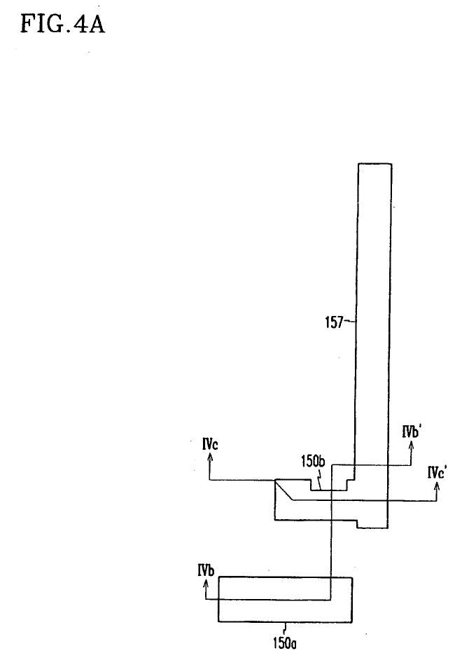

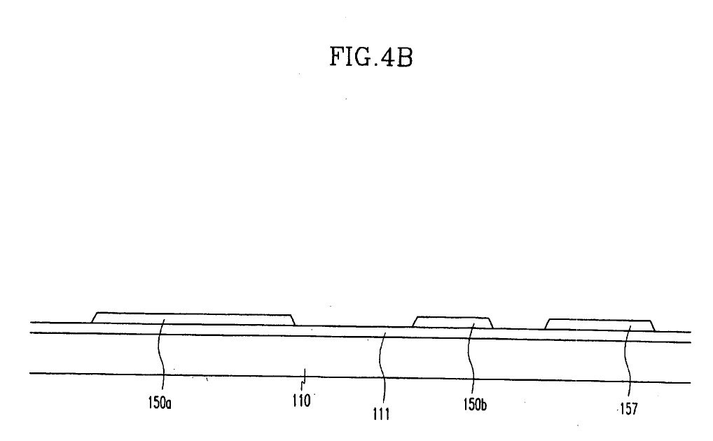

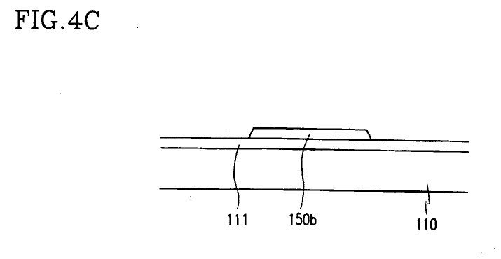

Now, a method of manufacturing the organic EL display panel shown in FIGS. 1-3 is described with reference to FIGS. 4A-7C as well as FIGS. 1-3.

FIGS. 4A, 5A, 6A and 7A are layout views of the organic EL display panel shown in FIGS. 1-3 in intermediate steps of a manufacturing method thereof according to an embodiment of the present invention, FIGS. 4B, 5B, 6B and 7B are sectional views of the organic EL display panels shown in FIGS. 4A, 5A, 6A and 7A taken along the lines IVB-IVB′, VB-VB′, VIB-VIB′, and VIIB-VIIB′, respectively, and FIGS. 4C-7C are sectional views of the organic EL display panels shown in FIGS. 4A, 5A, 6A and 7A taken along the lines IVC-IVC′, VC-VC′, VIC-VIC′, and VIIC-VIIC′, respectively.

Referring to FIGS. 4A-4C, a blocking layer 111 preferably made of silicon oxide is formed on an insulating substrate 110, and an amorphous silicon layer is deposited on the blocking layer 111. The deposition of the amorphous silicon layer 30 is preferably performed by LPCVD (low temperature chemical vapor deposition), PECVD (plasma enhanced chemical vapor deposition) or sputtering. Consecutively, the amorphous silicon layer is laser-annealed to be crystallized into a polysilicon layer.

Next, the polysilicon layer is photo-etched to form first and second transistor portions 150a and 150b and the storage electrode portion 157.

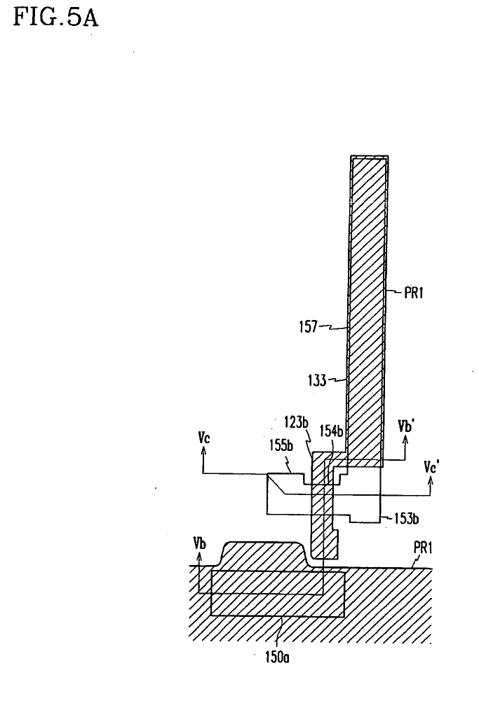

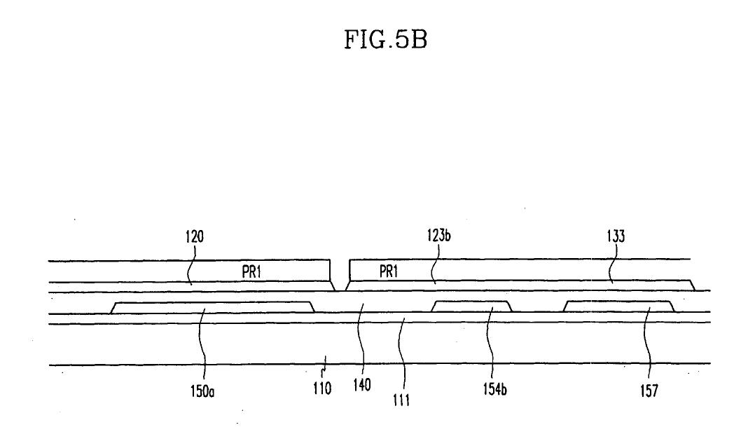

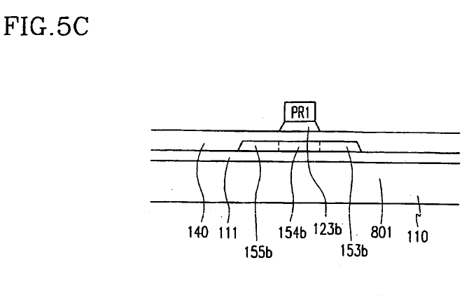

Referring to FIGS. 5A-5C, a gate insulating layer 140 is deposited on the polysilicon layer 150a, 150b and 157.

Successively, a gate metal layer 120 is deposited and a photoresist film is coated, exposed to light, and developed to form a first photoresist PR1. The gate metal layer 120 is etched by using the first photoresist PR1 as an etch mask to form a gate electrode 123b and a storage electrode 133. P type impurity is injected into exposed portions of the second transistor portion 150b of the polysilicon layer to form a source region 153b and a drain region 155b. At this time, the first transistor portion 150a of the polysilicon layer is covered with the first photoresist PR1 and the gate metal layer 120 to be protected.

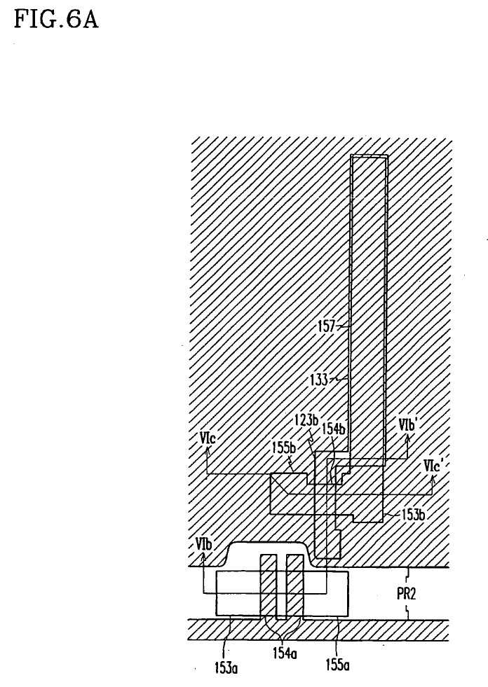

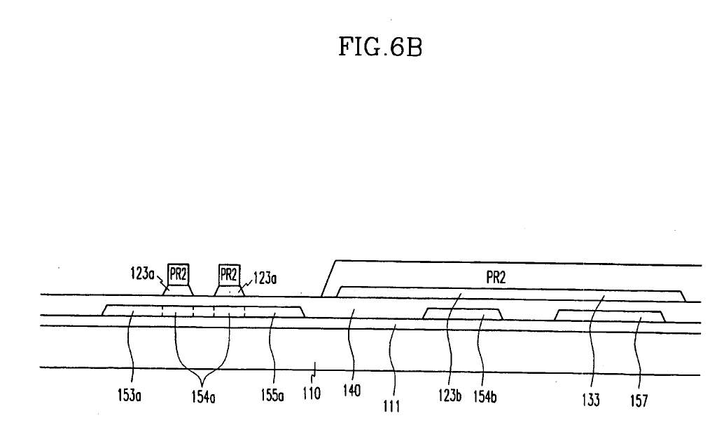

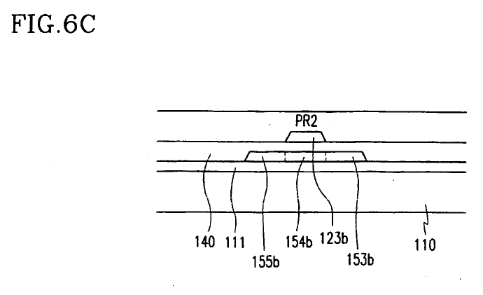

Referring to FIGS. 6A-6C, the first photoresist PR1 is removed and another photoresist film is coated, exposed to light, and developed to form a second photoresist PR2. The gate metal layer 120 is etched by using the first photoresist PR2 as an etch mask to form a gate electrode 123a and a gate line 121. N type impurity is injected into exposed portions of the first transistor portion 150a of the polysilicon layer to form a source region 153a and a drain region 155a. At this time, the second transistor portion 150b of the polysilicon layer is covered with the second photoresist PR2 to be protected.

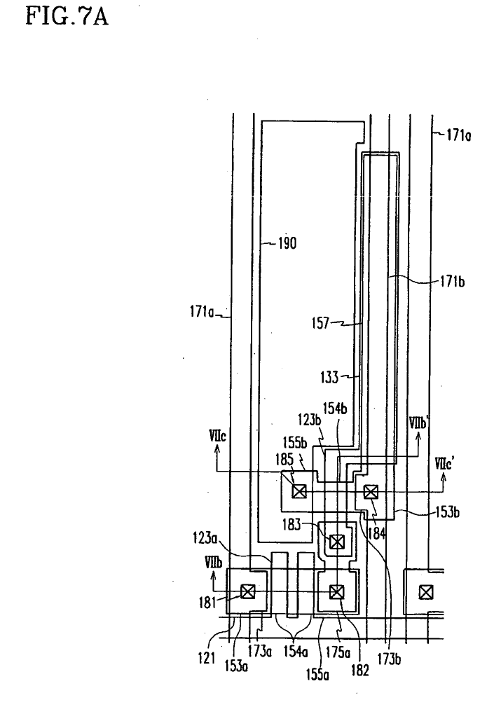

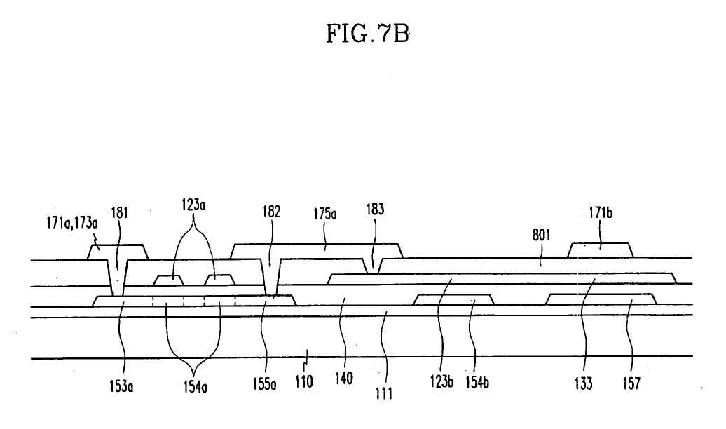

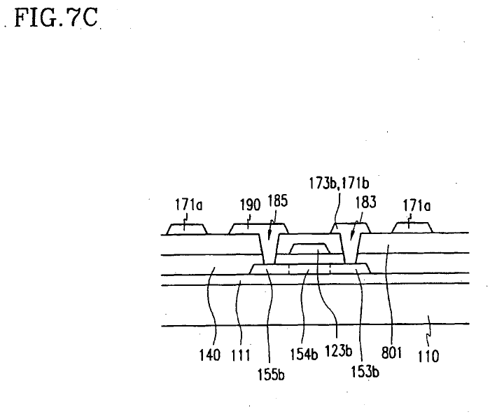

Referring to FIGS. 7A-7C, an interlayer insulating film 801 is deposited on the gate wire 121, 123a, 123b and 133. The interlayer insulating film 801 and the gate insulating layer 140 are photo-etched form a plurality of contact holes 181, 182, 184 and 185 exposing the first source region 153a, the first drain region 155a, the second source region 153b, and the second drain region 155b, respectively, as well as a contact hole 183 exposing an end portion of the second gate electrode 123b.

Thereafter, a data metal layer is deposited and photo-etched to form a data wire 171a, 171b, 173a, 173b and 175a and a pixel electrode 190. If the pixel electrode is made of transparent material such as ITO and IZO, it is formed by separate photo-etching step different from that for the data wire 171a, 171b, 173a, 173b, 175a.

Referring to FIGS. 1-3, an organic film containing black pigment is coated on the data wire 171a, 171b, 173a, 173b and 175a, and it is exposed to light and developed to form the partition 802. Thereafter, an organic EL layer 70 is formed on each pixel area by deposition or inkjet printing after masking. The organic EL layer 70 preferably has a multi-layered structure.

Next, an organic conductive material is deposited on the organic EL layer 70 to form a buffer layer 803, ITO or IZO is deposited on the buffer layer 803 to form a common electrode 270.

Although it is not shown in the figures, an auxiliary electrode made of low resistivity material such as Al may be formed before or after the formation of the common electrode 270. The common electrode 270 is preferably made of reflective metal if the pixel electrode 190 is formed of transparent conductive material.

The above-described manufacturing method of an organic EL display device reduces the manufacturing steps and time, thereby decreasing manufacturing cost.

Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

1. An organic EL display panel comprising:
an insulating substrate;
a polysilicon layer formed on the substrate;
a gate insulating layer formed on the polysilicon layer;
a gate wire formed on the gate insulating layer;
an interlayer insulating film formed on the gate wire;
a data wire formed on the interlayer insulating film;
a pixel electrode formed on the same layer as the data wire;
an organic EL layer formed on the pixel electrode and disposed in a predetermined area;
a partition formed on the data wire and the pixel electrode and defining the predetermined area; and
a common electrode formed on the organic EL layer and the partition.

2. The organic EL display panel of claim 1, wherein the pixel electrode includes the same material as the data wire.

3. The organic EL display panel of claim 1, wherein the polysilicon layer comprises first and second transistor portions including source regions and drain regions and a storage electrode portion connected to the second transistor portion, the gate wire comprises first and second gate electrodes and a storage electrode overlapping the first and the second transistor portions and the storage electrode portion, respectively, the data wire comprises first and second data lines, a first source electrode connected to the first data line and the source region of the first transistor portion, a first drain electrode connected to the drain region the first transistor portion and the second gate electrode, and a second source electrode connected to the second data line and the source region of the second transistor portion, and the pixel electrode is connected to the drain region of the second transistor.

4. The organic EL display panel of claim 1, further comprising a buffer layer disposed between the organic EL layer and the common electrode.

5. The organic EL display panel of claim 1, wherein the partition comprises black photoresist.

6. The organic EL display panel of claim 1, further comprising an auxiliary electrode contacting the common electrode.

7. A method of manufacturing an organic EL display panel, the method comprising:
forming a polysilicon layer on an insulating substrate;
forming a gate insulating layer on the polysilicon layer;
forming a gate line on the gate insulating layer;
forming an interlayer insulating film on the gate line;
forming a data line and a pixel electrode on the interlayer insulating film;
forming a partition on the data line and the pixel electrode;
forming an organic EL layer on the pixel electrode in a predetermined area defined by the partition; and
forming a common electrode on the organic EL layer.

8. The method of claim 7, wherein the formation of the partition comprises:
coating a black photoresist;
exposing the photoresist to light through a photo mask; and
developing the photoresist.

9. The method of claim 7, further comprising:
forming an auxiliary electrode contacting the common electrode.

10. The organic EL display panel of claim 2, wherein the polysilicon layer comprises first and second transistor portions including source regions and drain regions and a storage electrode portion connected to the second transistor portion, the gate wire comprises first and second gate electrodes and a storage electrode overlapping the first and the second transistor portions and the storage electrode portion, respectively, the data wire comprises first and second data lines, a first source electrode connected to the first data line and the source region of the first transistor portion, a first drain electrode connected to the drain region the first transistor portion and the second gate electrode, and a second source electrode connected to the second data line and the source region of the second transistor portion, and the pixel electrode is connected to the drain region of the second transistor.

11. The organic EL display panel of claim 2, further comprising a buffer layer disposed between the organic EL layer and the common electrode.

12. The organic EL display panel of claim 2, wherein the partition comprises black photoresist.

13. The organic EL display panel of claim 2, further comprising an auxiliary electrode contacting the common electrode.

14. The method of claim 8, further comprising:
forming an auxiliary electrode contacting the common electrode.
